(19) United States
(12) Patent Application Publication
(10) Pub. No.: US 2023/0197765 A1
(43) Pub. Date: Jun. 22, 2023

(54) DISPLAY DEVICE

(71) Applicant: Japan Display Inc., Tokyo (JP)

(72) Inventor: Akihiro OGAWA, Tokyo (JP)

(21) Appl. No.: 18/113,161

(22) Filed: Feb. 23, 2023

Related U.S. Application Data
(63) Continuation of application No. PCT/JP2021/030793, filed on Aug. 23, 2021.

(30) Foreign Application Priority Data
Aug. 28, 2020 (JP) 2020-144766

(51) Int. Cl. H01L 27/15

(52) U.S. Cl. CPC H01L 27/156

(57) ABSTRACT

According to one embodiment, a display device includes an organic planarization film, a second electrode, a light emitting element and a metal layer. The organic planarization film is arranged on a substrate and covers a pixel circuit. The second electrode is electrically connected to a first electrode of the pixel circuit, in an area overlapping with a first contact hole formed in the organic planarization film, in planar view. The light emitting element is electrically connected to the second electrode. The metal layer is arranged between the organic planarization film and the second electrode. The metal layer is arranged on an entire surface of the organic planarization film, except for the area overlapping with the first contact hole in planar view.

### CROSS-REFERENCE TO RELATED APPLICATIONS

This application is a Continuation Application of PCT Application No. PCT/JP2021/030793, filed Aug. 23, 2021, and based upon and claiming the benefit of priority from Japanese Patent Application No. 2020-144766, filed Aug. 28, 2020, the entire contents of all of which are incorporated herein by reference.

### FIELD

Embodiments described herein relate generally to a display device.

### BACKGROUND

Generally, an LED display using the light-emitting diode (LED) which is a self-luminous element is known but, recently, a display device (hereinafter referred to as a micro-LED display) using a minute diode element referred to as a micro-LED has been developed.

Since a number of chip-shaped micro-LEDs are mounted in a display area, unlike a conventional liquid crystal display or organic EL display, the micro-LED display can easily achieve both high definition and upsizing and is focused as a next generation display.

However, a problem arises that since the micro-LEDs have the characteristic of emitting and diffusing light in a plurality of directions, the display quality is likely to be degraded.

### BRIEF DESCRIPTION OF THE DRAWINGS

FIG. 1 is a perspective view schematically showing a configuration of a display device according to one of the embodiments.

FIG. 2 is an equivalent circuit diagram schematically showing a sub-pixel according to the embodiment.

FIG. 3 is view showing a circuit configuration of a plurality of sub-pixels according to the embodiment.

FIG. 4 is a cross-sectional view schematically showing a configuration example of a display panel according to a first embodiment.

FIG. 5 is a view schematically showing an example of a method of forming a display panel according to the embodiment.

FIG. 6 is a cross-sectional view schematically showing a configuration example of a display panel according to a comparative example.

FIG. 7 is a view schematically showing another example of the method of forming the display panel according to the embodiment.

FIG. 8 is a cross-sectional view schematically showing a configuration of a display panel according to a second embodiment.

FIG. 9 is a view schematically showing an example of a method of forming a display panel according to the embodiment.

FIG. 10 is a cross-sectional view schematically showing a configuration example of a display panel according to a third embodiment.

### DETAILED DESCRIPTION

In general, according to one embodiment, a display device includes a substrate, a pixel circuit, an organic planarization film, a second electrode, a light emitting element and a metal layer. The pixel circuit is arranged on the substrate. The organic planarization film is arranged on the substrate and covers the pixel circuit. The second electrode is electrically connected to a first electrode constituting the pixel circuit, in an area overlapping with a first contact hole formed in the organic planarization film, in planar view. The light emitting element is electrically connected to the second electrode. The metal layer is arranged between the organic planarization film and the second electrode. The metal layer is arranged on an entire surface of the organic planarization film, except for the area overlapping with the first contact hole in planar view.

Several embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

### First Embodiment

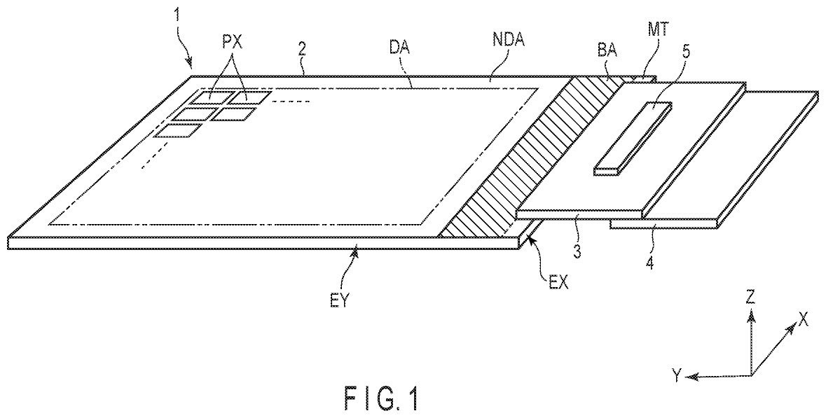

FIG. 1 is a perspective view schematically showing a configuration of a display device 1 according to one of the embodiments. FIG. 1 shows a three-dimensional space defined by a first direction X, a second direction Y perpendicular to the first direction X, and a third direction Z perpendicular to the first direction X and the second direction Y. Incidentally, the first direction X and the second direction Y are orthogonal to each other, but may intersect at an angle other than 90 degrees. In the present specification, viewing the display device 1 from a direction parallel to the third direction Z is referred to as planar view.

In the embodiment, a case where the display device 1 is a micro LED display using a micro LED which is a self-luminous element will be mainly described below.

As shown in FIG. 1, the display device 1 comprises a display panel 2, a first circuit board 3, a second circuit board 4, and the like.

The display panel 2 has, for example, a rectangular shape. In the example illustrated, short sides EX of the display panel 2 are parallel to the first direction X and long sides EY of the display panel 2 are parallel to the second direction Y. The third direction Z corresponds to a thickness direction of the display panel 2. The first direction X may be restated as a direction parallel to the short sides of the display device 1, the second direction Y may be restated as a direction parallel to the long sides of the display device 1, and the third direction Z may be restated as a thickness direction of the display device 1. A main surface of the display panel 2 is parallel to an X-Y plane defined by the first direction X and the second direction Y. The display panel 2 includes a display area DA (display portion) and a non-display area NDA (non-display portion) located outside the display area DA. The non-display area NDA includes a terminal area MT. In the example illustrated, the non-display area NDA surrounds the display area DA.

The display area DA is an area where images are displayed and includes, for example, a plurality of pixels PX arrayed in a matrix. The pixel PX includes a light emitting element (micro-LED), a switching element (drive transistor) for driving the light emitting element, and the like.

The terminal area MT is provided along the short sides EX of the display panel 2 and includes terminals for electrically connecting the display panel 2 to external devices and the like.

The first circuit board 3 is mounted on the terminal area MT and is electrically connected to the display panel 2. The first circuit board 3 is, for example, a flexible printed circuit board. The first circuit board 3 comprises a driver IC chip (hereinafter referred to as a panel driver) 5 which drives the display panel 2, and the like. Incidentally, in the example illustrated, the panel driver 5 is arranged on the first circuit board 3, but may be arranged under the first circuit board 3. Alternatively, the panel driver 5 may be mounted on a part other than the first circuit board 3. In this case, the panel driver 5 may be mounted on the non-display area NDA of the display panel 2 or may be mounted on the second circuit board 4. The second circuit board 4 is, for example, a rigid printed circuit board. For example, the second circuit board 4 is connected to the first circuit board 3 at a position under the first circuit board 3.

For example, the panel driver 5 is connected to a control board (not shown) via the second circuit board 4. For example, the panel driver 5 performs control of displaying images on the display panel 2 by driving a plurality of pixels PX, based on image signals output from the control boards.

Incidentally, the display panel 2 may include a bending area BA represented by hatch lines. The bending area BA is an area which is bended when the display device 1 is accommodated in a housing of an electronic apparatus or the like. The bending area BA is located on the terminal area MT side of the non-display area NDA. In a state in which the bending area BA is bended, the first circuit board 3 and the second circuit board 4 are arranged to be opposed to the display panel 2.

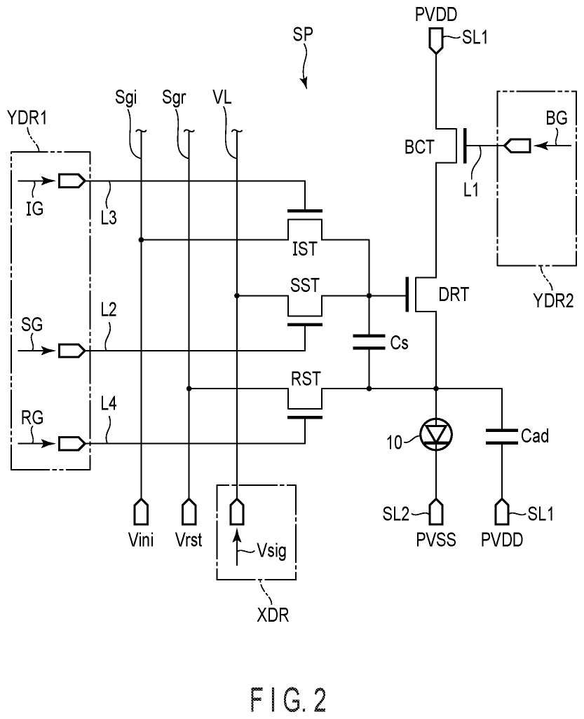

The FIG. 2 is an equivalent circuit diagram showing a sub-pixel SP included in the pixel PX. In the present embodiment, the pixel PX includes a plurality of sub-pixels SP. More specifically, the pixel PX includes a sub-pixel SP corresponding to a red light emitting element, a sub-pixel SP corresponding to a green light emitting element, a sub-pixel SP corresponding to a blue light emitting element, and the like. Each of the sub-pixels SP includes a light emitting element 10 and a pixel circuit which supplies a drive current to the light emitting element 10. The light emitting element 10 is, for example, a self-luminous element, and is a micro-LED in the present embodiment.

The pixel circuit of each of the sub-pixels SP is a voltage signal type pixel circuit that controls the light emission of the light emitting element 10 in accordance with a video signal Vsig formed of a voltage signal, and includes a reset switch RST, a pixel select switch SST, an initializing switch IST, an output switch BCT, a drive transistor DRT, a storage capacitor Cs, and an auxiliary capacitor Cad. The storage capacitor Cs and the auxiliary capacitor Cad are the capacitors. The auxiliary capacitor Cad is an element provided to adjust the amount of a light emission current and may be unnecessary in some cases.

The reset switch RST, the pixel select switch SST, the initializing switch IST, the output switch BCT, and the drive transistor DRT are composed of thin-film transistors (TFTs). In the present embodiment, the reset switch RST, the pixel select switch SST, the initializing switch IST, the output switch BCT, and the drive transistor DRT are configured by TFTs of the same conductivity type, for example, N-channel type. Incidentally, the reset switch RST, the pixel select switch SST, the initializing switch IST, the output switch BCT, and the drive transistor DRT may be configured by P-channel TFTs. In this case, N-channel TFTs and P-channel TFTs may be formed at the same time. The reset switch RST, the pixel select switch SST, the initializing switch IST, and the output switch BCT need only to function as switches, and do not need to be configured by TFTs.

In the display device 1 according to the present embodiment, all the TFTs constituting the drive transistor DRT and the switches are bottom-gate thin film transistors formed to have the same structure through the same processes.

Each of the reset switch RST, the pixel select switch SST, the initializing switch IST, the output switch BCT, and the drive transistor DRT includes a source electrode, a drain electrode, and a gate electrode.

In the pixel circuit of the sub-pixel SP, the drive transistor DRT and the output switch BCT are connected in series with the light emitting element 10 at positions between a first power line SL1 and a second power line SL2. The first power line SL1 is a high potential power line fixed to a high potential PVDD, and the second power line SL2 is a low potential power line fixed to a low potential PVSS. The light emitting device 10 ideally emits light when a drive current is supplied by the potential difference between the high potential PVDD and the low potential PVSS. In other words, the high potential PVDD has a potential difference from the low potential PVSS, which makes the light emitting element 10 emit light. More specifically, the high potential PVDD is set to a potential of, for example, 10V, and the low potential PVSS is set to a potential of, for example, 1.5V.

In the output switch BCT, a drain electrode is connected to the first power line SL1, a source electrode is connected to the drain electrode of the drive transistor DRT, and a gate electrode is connected to an output control signal line Ll. The output switch BCT is thereby controlled to be turned on (conductive state) or off (non-conductive state) by a control signal BG supplied to the output control signal line L1. The output switch BCT controls the light emission time of the light emitting element 10 in response to the control signal BG.

In the drive transistor DRT, a drain electrode is connected to the source electrode of the output switch BCT, and a source electrode is connected to one of electrodes (anode) of the light emitting element 10. The other electrode (cathode) of the light emitting element 10 is connected to the second power line SL2. The drive transistor DRT outputs a drive current having a current amount corresponding to the video signal Vsig to the light emitting element 10.

In the pixel select switch SST, a source electrode is connected to a video signal line VL, a drain electrode is connected to the gate electrode of the drive transistor DRT, and a gate electrode is connected to a pixel selection control signal line L2. The pixel select switch SST is controlled to be turned on and off by a control signal SG supplied from the pixel selection control signal line L2. The pixel switch SST controls connection and disconnection between the pixel circuit and the video signal line VL, and takes the video signal Vsig from the video signal line VL in the pixel circuit.

In the initializing switch IST, a source electrode is connected to the initialization line Sgi, a drain electrode is connected to the gate electrode of the drive transistor DRT, and a gate electrode is connected to an initialization control signal line L3. The initializing switch IST is controlled to be turned on and off by a control signal IG supplied from the initialization control signal line L3. The initializing switch IST controls connection and disconnection between the pixel circuit and the initialization line Sgi in response to the control signal IG. An initial potential (initialization voltage) Vini can be taken in the pixel circuit from the initialization line Sgi by connecting the pixel circuit with the initialization line Sgi by the initializing switch IST.

In the reset switch IST, a source electrode is connected to a reset line Sgr, a drain electrode is connected to the gate electrode of the drive transistor DRT, and a gate electrode is connected to a reset control signal line L4. The reset line Sgr is connected to a reset power supply and fixed to a reset potential Vrst that is a constant potential. The reset switch RST is controlled to be turned on and off by a control signal RG supplied via the reset control signal line L4. The potential of the source electrode of the drive transistor DRT can be reset to the reset potential Vrst by switching the reset switch RST to be turned on.

The storage capacitor Cs is electrically connected between the gate electrode and the source electrode of the drive transistor DRT, as an equivalent circuit. The auxiliary capacitor Cad is connected between the source electrode of the drive transistor DRT and the first power line SL1 serving as a constant potential line, as an equivalent circuit.

The panel driver 5 shown in FIG. 1 controls the scanning line drive circuits YDR1 and YDR2 and the signal line drive circuit XDR. The panel driver 5 receives a digital video signal and a synchronization signal supplied from the outside, and generates a vertical scanning control signal for controlling vertical scanning timing and a horizontal scanning control signal for controlling horizontal scanning timing, based on the synchronization signal.

The panel driver 5 supplies each of the vertical scanning control signal and the horizontal scanning control signal to the scanning line drive circuits YDR1 and YDR2 and the signal line drive circuit XDR, and supplies the digital video signal and the initialization signal to the signal line drive circuit XDR in synchronization with the horizontal scanning timing and the vertical scanning timing.

The signal line drive circuit XDR converts the video signals sequentially obtained in each of horizontal scanning periods under control of the horizontal scanning control signal, in an analog format, and supplies the video signals Vsig corresponding to gradation to a plurality of video signal lines VL. The panel driver 5 fixes the first power line SL1 to the high potential PVDD, fixes the reset line Sgr to the reset potential Vrst, and fixes the initialization line Sgi to the initialization potential Vini. Incidentally, the potential of the first power line SL1, the potential of the reset line Sgr, and the potential of the initialization line Sgi may be set via the signal line drive circuit XDR.

Incidentally, the circuit configuration of the sub-pixel SP described with reference to FIG. 2 is an example, and the circuit configuration of the sub-pixel SP may be the other configuration if the circuit configuration includes at least the drive transistor DRT and the light emitting element 10. For example, several elements of the circuit configuration of the sub-pixel SP described with reference to FIG. 2 may be omitted or other elements may be added thereto.

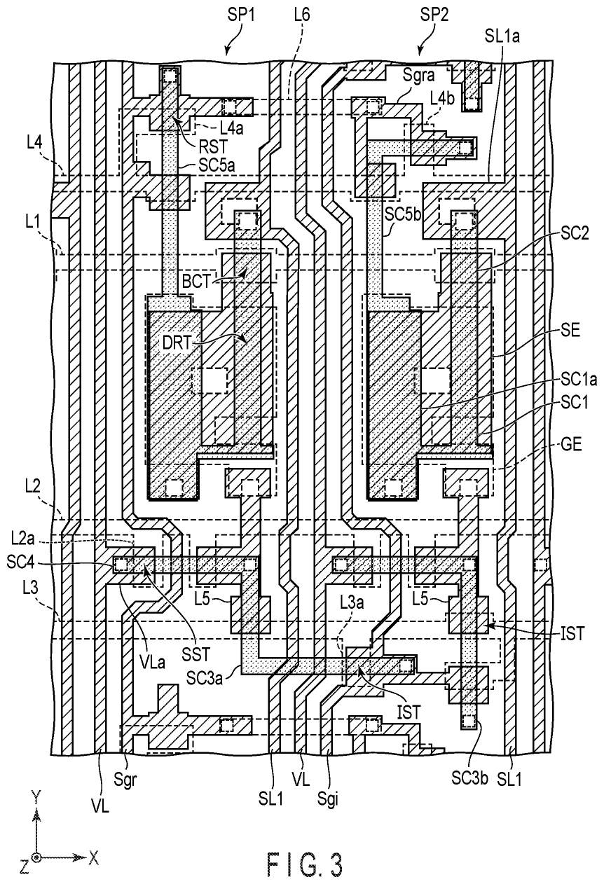

FIG. 3 shows the circuit configuration of two sub-pixels SP1 and SP2 adjacent to each other in the first direction X. As shown in FIG. 3, a plurality of video signal lines VL, a plurality of first power supply lines SL1, the reset line Sgr, and the initialization line Sgi extend in the second direction Y. The output control signal line L1, the pixel selection control signal line L2, the initialization control signal line L3, and the reset control signal line L4 extend in the first direction X and intersect each of the plurality of video signal lines VL, the plurality of first power supply lines SL1, the reset line Sgr, and the initialization line Sgi in planar view. In addition, a connection line L5 is provided between two first power supply lines SL1 that are arranged at intervals in the first direction X. The connection line L5 connects the drive transistor DRT, the pixel select switch SST, and the initializing switch IST.

As shown in FIG. 3, the reset line Sgr and the initialization line Sgi are shared by two sub-pixels SP1 and SP2 adjacent to each other in the first direction X. In other words, the initialization line Sgi is not provided in the sub-pixel SP1 shown on the left side of FIG. 3, but the reset line Sgr is provided along the video signal line VL of the sub-pixel SP1. In contrast, the reset line Sgr is not provided in the sub-pixel SP2 shown on the right side of FIG. 3, but the initialization line Sgi is provided along the video signal line VL of the sub-pixel SP2. Thus, the lines can be arranged efficiently while reducing the number of lines as compared with a case where the reset line Sgr and the initialization line Sgi are provided, for each of the sub-pixels SP1 and SP2.

The drive transistor DRT includes a semiconductor layer SC1, a source electrode SE and a gate electrode GE. The semiconductor layer SC1, the source electrode SE, and the gate electrode GE are arranged to overlap at least partially in planar view and are provided in an area surrounded by two first power supply lines SL1 arranged at intervals in the first direction X, the output control signal line Ll, and the pixel selection control signal line L2.

The semiconductor layer SC1 is connected to a first partial semiconductor layer SC1a. The first partial semiconductor layer SC1a is formed of the same semiconductor material as the semiconductor layer SC1, in the same layer as the semiconductor layer SC1. The first partial semiconductor layer SC1a is provided alongside the semiconductor layer SC1 in the first direction X, and a width of the first partial semiconductor layer SC1a in the first direction X is larger than the width of the semiconductor layer SC1 in the first direction X. The first partial semiconductor layer SC1a is provided to overlap with the gate electrode GE, and the storage capacitor Cs is formed between the first partial semiconductor layer SC1a and the gate electrode GE. Incidentally, the semiconductor layer SC1 and the first partial semiconductor layer SC1a may be composed of a single rectangular semiconductor layer.

The output switch BCT includes a semiconductor layer SC2. The semiconductor layer SC2 is connected to the semiconductor layer SC1 and intersects the output control signal line L1 in planar view. A channel area is formed in an area overlapping the output control signal line L1, of the semiconductor layer SC2. The portion of the output control signal line L1, which overlaps with the semiconductor layer SC2, functions as the gate electrode of the output switch BCT. One end side of the semiconductor layer SC2 is electrically connected to the first power line connecting portion SL1a. The first power line connecting portion SL1a is the portion branched from the first power line SL1 in the first direction X. As a result, the PVDD potential is supplied from the first power line SL1 to the drive transistor DRT and the output switch BCT.

In the sub-pixel SP1 shown on the left side of FIG. 3, the initializing switch IST includes a semiconductor layer SC3a. In contrast, in the sub-pixel SP2 shown on the right side of FIG. 3, the initializing switch IST includes a semiconductor layer SC3b. The semiconductor layer SC3a intersects a branch signal line L3a, which is branched from the initialization control signal line L3, in planar view. A channel area is formed in an area overlapping with the semiconductor layer SC3a, of the semiconductor layer SC3a. The portion overlapping with the semiconductor layer SC3a, of the branch signal line L3a, serves as the gate electrode of the initializing switch IST of the sub-pixel SP1. The semiconductor layer SC3b intersects the initialization control signal line L3 in planar view. A channel area is formed in an area overlapping with the initialization control signal line L3, of the semiconductor layer SC3b. The portion overlapping with the semiconductor layer SC3b, of the initialization control signal line L3, functions as the gate electrode of the initializing switch IST of the sub-pixel SP2.

In the sub-pixel SP1 shown on the left side of FIG. 3, the semiconductor layer SC3a includes a portion extending in the second direction Y and a portion extending in the first direction X. One end of the portion extending in the second direction Y, of the semiconductor layer SC3a, is electrically connected to the connection line L5. The portion extending in the first direction X, of the semiconductor layer SC3a, intersects the first power line SL1 and the video signal line VL in planar view, extends to the sub-pixel SP2, and is electrically connected to the initialization line Sgi. In the sub-pixel SP2 shown on the right side of FIG. 3, the semiconductor layer SC3b extends in the second direction Y, with one end electrically connected to the connection line L5 and the other end connected to the initialization line Sgi. In the above configuration, one initialization line Sgi is electrically connected to two initializing switches IST and is shared by two sub-pixels SP1 and SP2 adjacent in the first direction X.

The pixel select switch SST includes a semiconductor layer SC4. The semiconductor layer SC4 extends in the first direction X and intersects a branch signal line L2a, which is branched from the pixel selection control signal line L2, in planar view. A channel area is formed in an area overlapping with the branch signal line L2a, of the semiconductor layer SC4. The portion overlapping with the semiconductor layer SC4, of the branch signal line L2a, functions as the gate electrode of the pixel select switch SST. One end of the semiconductor layer SC4 is connected to a video signal line connecting portion VLa, and the other end is connected to the connection line L5. The video signal line connecting portion VLa is the portion branched from the video signal line VL in the first direction X.

In the sub-pixel SP1 shown on the left side of FIG. 3, the reset switch RST includes a semiconductor layer SC5a. In contrast, in the sub-pixel SP2 shown on the right side of FIG. 3, the reset switch RST includes a semiconductor layer SC5b. The semiconductor layer SC5a extends in the second direction Y and intersects the reset control signal line L4 and a branch signal line L4a branched from the reset control signal line L4, in planar view. A channel area is formed in an area overlapping with the branch signal line L4a, of the semiconductor SC5a. The portion overlapping with the semiconductor layer SC5a, of the branch signal line L4a functions as the gate electrode of the reset switch RST of the sub-pixel SP1. The semiconductor layer SC5b includes a portion extending in the second direction Y and a portion extending in the first direction X. The portion extending in the second direction Y, of the semiconductor layer SC5b, intersects the reset control signal line L4 in planar view, and the portion extending in the first direction X intersects a branch signal line L4b branched from the reset control signal line L4 in planar view. A channel area is formed in an area overlapping with the reset control signal line L4, of the semiconductor layer SC5b. The portion overlapping with the semiconductor layer SC5b, of the reset control signal line L4, functions as the gate electrode of the reset switch RST of the sub-pixel SP2.

In the sub-pixel SP1 shown on the left side of FIG. 3, one end of the semiconductor layer SC5a is connected to the reset line Sgr. In addition, in the sub-pixel SP2 shown on the right side of FIG. 3, one end of the semiconductor layer SC5b is connected to a reset line connecting portion Sgra formed in an island shape in the same layer as the reset line Sgr. In addition, the other ends of the semiconductor layers SC5a and SC5b are both electrically connected to the semiconductor layer SC2 via the first partial semiconductor layer SC1a. The reset line Sgr and the reset line connecting portion Sgra are connected to each other by a bridge portion L6. The bridge section L6 is formed in the same layer as the reset control signal line L4, i.e., in the same layer as various gate electrodes. According to this, the reset line Sgr and the reset line connecting portion Sgra are electrically connected to each other via the bridge portion L6. In the above configuration, one reset line Sgr is electrically connected to two reset switches RST and is shared by two sub-pixels SP1 and SP2 adjacent to each other in the first direction X.

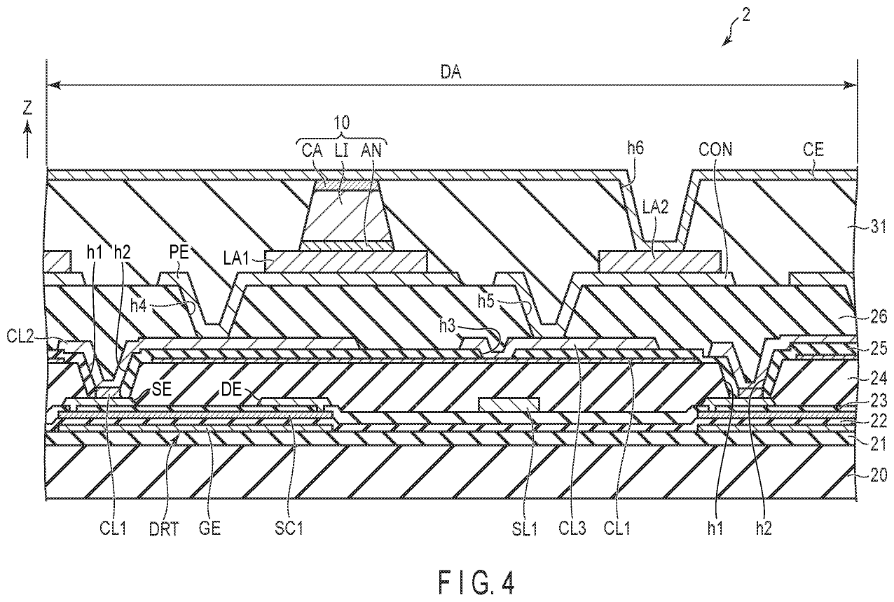

FIG. 4 is a cross-sectional view schematically showing a configuration example of the display panel 2 according to a first embodiment. Incidentally, in FIG. 4, the display panel 2 is drawn such that the display surface, i.e., the light emission surface faces upward and the back surface faces downward.

As shown in FIG. 4, the display panel 2 comprises an insulating base 20, insulating layers 21 to 26 provided on the insulating base 20, and the plurality of sub-pixels SP. The sub-pixels SP are provided on the insulating base 20, located in the display area DA, and comprise the light emitting elements 10.

A glass substrate of quartz, alkali-free glass, and the like or a resin substrate of polyimide or the like can be mainly used as the insulating base 20. The material of the insulating base 20 may be any material withstanding a processing temperature during manufacturing the TFT. When the insulating base 20 is a flexible resin substrate, the display device 1 can be constituted as a sheet display. The resin substrate may be formed of not polyimide, but the other resin material. Incidentally, when polyimide or the like is used for the insulating base 20, the insulating base 20 may be referred to as an organic insulating layer or a resin layer, more appropriately, in some cases.

The insulating layer 21 is provided on the insulating base 20. Various types of TFTs are formed on the insulating layer 21. In the display area DA, the drive transistor DRT and the like are formed on the insulating layer 21. In FIG. 4, illustration of various switches RST, SST, IST, and BCT other than the drive transistor DRT is omitted. The driver transistor DRT comprises a semiconductor layer SC1, a gate electrode GE, a source electrode SE (first electrode), and a drain electrode DE.

The gate electrode GE is arranged on the insulating layer 21. The insulating layer 22 is provided on the insulating layer 21 and the gate electrode GE. The insulating layer 22 functions as a gate insulating film. The semiconductor layer SC1 is arranged on the insulating layer 22. The gate electrode GE and the channel area of the semiconductor layer SC1 are opposed to each other. The insulating layer 23 is provided on the insulating layer 22 and the semiconductor layer SC1. The source electrode SE and the drain electrode DE are arranged on the insulating layer 23. The source electrode SE and the drain electrode DE are electrically connected to the semiconductor layer SC1 through contact holes formed in the insulating layer 23. The contact holes for electrically connecting the source electrode SE and the semiconductor layer SC1 do not overlap with a contact hole h1 to be described below, in planar view. The first power line SL1 is further provided on the insulating layer 23.

The insulating layer 24 is provided on the insulating layer 23, the source electrode SE, the drain electrode DE, and the first power line SL1. The insulating layer 24 covers the plurality of TFTs such as the drive transistor DRT. The contact hole h1 is formed in the insulating layer 24. The contact hole h1 exposes an upper surface of the source electrode SE.

A conductive layer CL1 (metal layer) is provided on the insulating layer 24 and the source electrode SE. The insulating layer 25 is provided on the insulating layer 24 and the conductive layer CL1. The insulating layer 25 includes a contact hole h2 surrounded by the contact hole h1, and the contact hole h2 exposes an upper surface of the conductive layer CL1 which is arranged in an island shape on the source electrode SE. In addition, a contact hole h3 which exposes the upper surface of the conductive layer CL1 opposed to the conductive layer CL3 is formed in the insulating layer 25.

Conductive layers CL2 and CL3 are arranged on the insulating layer 25. The conductive layer CL2 (second electrode) is in contact with the conductive layer CL1 arranged on the source electrode SE and is electrically connected to the source electrode SE via the conductive layer CL1, through the contact hole h2 formed in the insulating layer 25. The conductive layer CL3 is in contact with the conductive layer CL1 through the contact hole h3 formed in the insulating layer 25. Incidentally, a predetermined capacitance is formed between the conductive layer CL1 and the conductive layer CL2 which are opposed to each other with the insulating layer 25 interposed therebetween.

The insulating layer 26 is provided on the insulating layer 25, the conductive layer CL2, and the conductive layer CL3. A contact hole h4 is formed in the insulating layer 26, and the contact hole h4 exposes an upper surface of the conductive layer CL2. In addition, a contact hole h5 is formed in the insulating layer 26, and the contact hole h5 exposes an upper surface of the conductive layer CL3.

The pixel electrode PE is arranged on the insulating layer 26. The pixel electrode PE is in contact with the conductive layer CL2 through the contact hole h4 formed in the insulating layer 26 and is connected to the conductive layer CL2. The pixel electrode PE is electrically connected to the source electrode SE of the drive transistor DRT via the conductive layer CL2 and the conductive layer CL1 which is arranged in an island shape on the source electrode SE. A signal whose current value is controlled is supplied to the pixel electrode PE from the drive transistor DRT.

In the present embodiment, the display panel 2 includes a contact electrode CON, a connection layer LA1, and a connection layer LA2. The contact electrode CON is provided on the insulating layer 26 and is located at an insulating distance from the pixel electrode PE. The contact electrode CON is in contact with the conductive layer CL3 through the contact hole h5 formed in the insulating layer 26. The connection layer LA1 is arranged on the pixel electrode PE. In planar view, the connection layer LA1 does not overlap with the contact hole h4. The connection layer LA2 is arranged on the contact electrode CON. In planar view, the connection layer LA2 does not overlap with the contact hole h5.

The insulating layers 21 to 26 are formed of an inorganic insulating material or an organic insulating material. In the present embodiment, the insulating layers 21, 22, 23, and 25 are formed of, for example, silicon oxide (SiO₂) or silicon nitride (SiN) as the inorganic insulating material.

The insulating layers 24 and 26 are formed of a resin material such as a photosensitive acrylic resin as the organic insulating material. Each of the insulating layers 24 and 26 has a flat surface on the side opposed to the light emitting element 10, and functions as a planarizing layer. In the present embodiment, the insulating layer 24 provided above the insulating base 20 functions as a first organic planarization film, and the insulating layer 26 provided above the insulating layer 24 functions as a second organic planarization film.

The gate electrode GE is formed of metal as a conductive material. For example, the gate electrode GE is formed of molybdenum/tungsten (MoW). The semiconductor layer SC1 is formed of low temperature polysilicon as polysilicon. However, the semiconductor layer SC1 may be formed of a semiconductor other than polysilicon, such as amorphous silicon or an oxide semiconductor.

The source electrode SE, the drain electrode DE, and the first power line SL1 are located in the same layer and are formed of a metal as the same conductive material. For example, each of the source electrode SE, the drain electrode DE, and the first power line SL1 adopts a three-layer stacked structure (Ti-based/Al-based/Ti-based), and includes a lower layer formed of metal materials containing titanium (Ti) as a main component, such as Ti and an alloy containing Ti, an intermediate layer formed of metal materials containing aluminum (Al) as a main component, such as Al and an alloy containing Al, and an upper layer formed of metal materials containing Ti as a main component, such as Ti and an alloy containing Ti.

The conductive layer CL1 is formed of a metal having a high reflectivity. For example, the conductive layer CL1 has a two-layer stacked structure, and includes a lower layer formed of a metal material containing Mo as a main component, such as Mo or an alloy containing Mo, and an upper layer formed of a metal material containing Al as a main component, such as Al or an alloy containing Al.

The conductive layers CL2 and CL3, the pixel electrode PE, and the contact electrode CON are formed of a metal as a conductive material. For example, the conductive layers CL2 and CL3, the pixel electrode PE, and the contact electrode CON have a two-layer stacked structure, and includes a lower layer formed of a metal material containing Mo as a main component, such as Mo or an alloy containing Mo, and an upper layer formed of a metal material containing Al as a main component, such as Al or an alloy containing Al. The conductive layers CL2 and CL3 are desirably located in the same layer and formed of a metal as the same conductive material. In addition, the pixel electrode PE and the contact electrode CON are desirably located in the same layer and are formed of a metal as the same conductive material.

The connection layers LA1 and LA2 are formed of solder.

The light emitting element 10 is mounted above the pixel electrode PE in the display area DA. More specifically, the light emitting element 10 is mounted on the connection layer LA1. The light emitting element 10 includes an anode AN serving as a first polar electrode, a cathode CA serving as a second polar electrode, and a light emitting layer LI which emits light. The anode AN and the cathode CA may be referred to as upper and lower electrodes as a whole. Alternatively, the anode AN may be referred to as a lower electrode, and the cathode CA may be referred to as an upper electrode.

In the light emitting element 10, the anode AN is located on a surface on the side opposed to the pixel electrode PE and is electrically connected to the pixel electrode PE. In the present embodiment, the anode AN is located on the connection layer LA1 and is in contact with the connection layer LA1. In the light emitting element 10, the cathode CA is located on a surface on a side opposite to the surface where the anode AN is located. In the light emitting element 10, the light emitting layer LI is located between the anode AN and the cathode CA.

A resin layer 31 is provided on the insulating layer 26, the pixel electrode PE, the contact electrode CON, the connection layer LA1, the connection layer LA2, and the light emitting element 10. The resin layer 31 is filled in the voids between the plurality of light emitting elements 10 provided in each sub-pixel SP. The resin layer 31 aim to inhibit moisture and the like entering from the outside and functions as a sealing film. The resin layer 31 has a flat surface on the side opposite to the side opposed to the insulating layer 26. For this reason, the resin layer 31 also functions as a planarizing layer. The resin layer 31 exposes the surface of the cathode CA, of the light emitting element 10.

Incidentally, the resin layer 31 may have a thickness that does not reach the cathode CA of the light emitting element 10. Parts of the unevenness caused by the mounting of the light emitting elements 10 remain on the surface on which the common electrode CE is formed, but the material for forming the common electrode CE may continuously cover the parts without breakage.

The common electrode CE is located in at least the display area DA, is arranged on the resin layer 31 and the light emitting element 10, and covers the resin layer 31 and the light emitting element 10. The common electrode CE is in contact with the cathodes CA of the plurality of light emitting elements 10 provided in each of sub-pixels SP and are electrically connected to the cathodes CA of the plurality of light emitting elements 10. In other words, the common electrode CE is shared by the plurality of sub-pixels SP (pixels PX).

The common electrode CE needs to be formed as a transparent electrode to take out the light emitted from the light emitting element 10, and is formed of, for example, indium tin oxide (ITO) or indium zinc oxide (IZO) as a transparent conducting material.

The common electrode CE is electrically connected to the contact electrodes CON through a contact hole h6 formed in the resin layer 31. In the present embodiment, the common electrode CE is in contact with the connection layer LA2 of the sub-pixel SP through the contact hole h6. Since the common electrode CE is in contact with not the contact electrode CON, but the connection layer LA2, ohmic contact can be formed between the common electrode CE and the connection layer LA2.

As described above, the display panel 2 has a structure from the insulating base 20 to the common electrode CE. Incidentally, a cover member such as cover glass, an optical layer such as a polarizer, a touch panel substrate, and the like may be further provided on the common electrode CE.

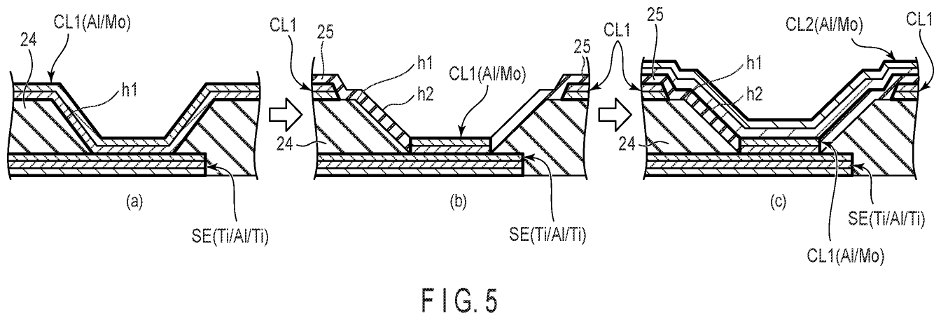

An example of a method of forming a stacked layer body from the conductive layer CL1 to the conductive layer CL2 (a stacked layer body composed of the conductive layer CL1, the insulating layer 25, and the conductive layer CL2) will be described with reference to FIG. 5. It is assumed here that the source electrode SE of the drive transistor DRT has a three-layer stacked structure of Ti/Al/Ti and that the conductive layers CL1 and CL2 have a two-layer stacked structure of Al/Mo.

First, as shown in FIG. 5(a), the conductive layer CL1 is formed on the insulating layer 24 and the source electrode SE. It is assumed here that the contact hole h1 is already formed in the insulating layer 24. The conductive layer CL1 is in contact with the source electrode SE through the contact hole h1. Although illustration is omitted in FIG. 5, a resist film is formed on the conductive layer CL1 except for a part which is in contact with the side surface (sloping surface) of the contact hole h1 after the state shown in FIG. 5(a). Since the resist film is also formed on the conductive layer CL1 arranged on the source electrode SE, removing the source electrode SE together with the conductive layer CL1 during wet etching to be described later can be controlled. After that, wet etching is executed to remove the conductive layer CL1 which is in contact with the side surface of the contact hole h1. The resist film formed on the conductive layer CL1 is removed after wet etching is ended.

Next, the insulating layer 25 is formed to cover the conductive layer CL1 and the insulating layer 24 (contact hole h1). Then, a resist film is formed on the insulating layer 25 except for the insulating layer 25 on the conductive layer CL1 arranged in an island shape on the source electrode SE. After that, dry etching is executed, the insulating layer 25 on the conductive layer CL1 arranged in an island shape on the source electrode SE is removed, and the contact hole h2 surrounded by the contact hole h1 is formed in the insulating layer 25 as shown in FIG. 5(b). According to this, as shown in FIG. 5(b), the surface of the conductive layer CL1 arranged in an island shape on the source electrode SE is exposed by the contact hole h2. The resist film formed on the insulating layer 25 is removed after dry etching is ended.

After that, as shown in FIG. 5(c), the conductive layer CL2 is formed to cover the insulating layer 25 and the conductive layer CL1 (contact hole h2) arranged in an island shape on the source electrode SE. The conductive layer CL2 is in contact with the conductive layer CL1 through the contact hole h2. In other words, the conductive layer CL2 is electrically connected to the source electrode SE through the conductive layer CL1.

The stacked layer body from the conductive layer CL1 to the conductive layer CL2 is formed by the method described above. As shown in FIG. 5(c), the source electrode SE is in contact with the conductive layer CL1, and the conductive layer CL1 is in contact with the conductive layer CL2. In the area where the contact hole h2 is formed (more precisely, in the area overlapping with the contact hole h2 (or the contact hole h1) in planar view), the source electrode SE, the conductive layer CL1, and the conductive layer CL2 overlap in planar view, and Al/Mo/Al/Mo/Ti/Al/Ti are stacked in this order from the upper layer to the lower layer.

Advantages of the display device 1 (display panel 2) according to the present embodiment will be described with reference to a comparative example. Incidentally, the comparative example is intended to describe parts of the effects that can be achieved by the display panel 2 according to the present embodiment and do not exclude effects common to the comparative example and the present embodiment from the scope of the present invention.

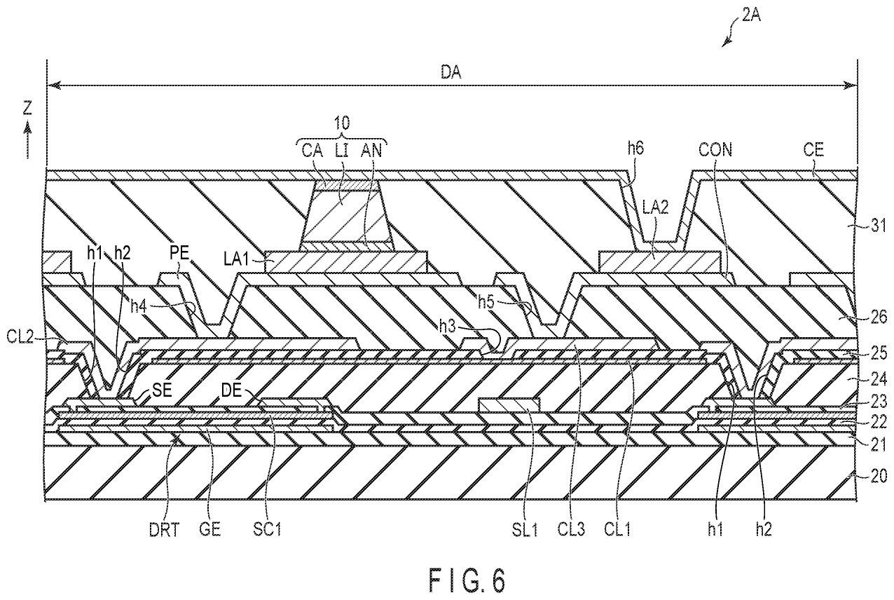

FIG. 6 is a cross-sectional view schematically showing a configuration example of the display panel 2A according to the comparative example. The display panel 2A according to the comparative example is different from the present embodiment in that the conductive layer CL1 is not formed of a metal but a transparent conductive material such as ITO.

Incidentally, in FIG. 6, the conductive layer CL1 is not illustrated with hatch lines but points (dots) to clarify the difference from FIG. 4. In addition, the display panel 2A according to the comparative example is also different from the present embodiment in that the conductive layer CL1 is not provided on the source electrode SE and that the source electrode SE is in contact with the conductive layer CL2.

In general, the conductive layer CL1 is often formed of a transparent conductive material such as ITO, similarly to the display panel 2A according to the comparative example. According to this, while an aperture ratio can be increased, a problem arises that since light emitted downward from the light emitting layer LI of the light emitting element 10 (epi-illumination light) is transmitted, the epi-illumination light may hit the TFT such as the drive transistor DRT and leakage current may flow.

In contrast, according to the display panel 2 of the present embodiment, since the conductive layer CL1 located under the light emitting layer LI of the light emitting element 10 is formed of a metal having a two-layer stacked structure of Al/Mo, the epi-illumination light can be reflected toward the upper surface (display surface). According to this, it is possible to suppress the epi-illumination light hitting the TFT such as drive transistor DRT and to suppress flow of the leakage current caused by the epi-illumination light.

In addition, according to the display panel 2 of the present embodiment, the luminance efficiency can also be improved since the epi-illumination light can be reflected toward the upper surface (display surface) as described above. Furthermore, since the material of the conductive layer CL1 is only changed from a transparent conductive material to a metallic material in the display panel 2 of the present embodiment, the advantage can be obtained that in obtaining the various effects described above, the number of processes do not need to be increased from the number of processes required to manufacture the display panel 2A according to the comparative example. In addition, according to the display panel 2 of the present embodiment, since the conductive layer CL1 is formed of a metal, the electrical resistance value can be lowered as compared with the comparative example in which the conductive layer CL1 is formed of a transparent conductive material, and the occurrence of non-uniformity in luminance can also be suppressed.

Furthermore, in the display panel 2 according to the present embodiment, the heat dissipation effect can also be increased since the metal layer can be increased as compared with the comparative example in which the conductive layer CL1 is formed of a transparent conductive material. As described above, the light emitting element 10 provided in the display panel 2 according to the present embodiment is a micro LED, which is a type of self-luminous element. Generally, it is known that the energy conversion efficiency of the micro-LED is approximately 30% and the remaining 70% are generated as heat. In other words, the micro-LED has a problem of emitting a large amount of heat when emitting light, and measures to dissipate the heat need to be taken. In the display panel 2 according to the present embodiment, since the conductive layer CL1 is formed of a metal, the conductive layer CL1 can be made to function as a so-called thermal interface material (TIM) and the heat dissipation effect can be increased. According to this, it is possible to efficiently dissipate the heat emitted when the micro-LED emits light.

In addition, in the display panel 2 according to the present embodiment, as shown in FIG. 5, the conductive layer CL1 remains on the source electrode SE since the resist film is also formed on the conductive layer CL1 arranged on the source electrode SE to prevent the source electrode SE from being removed in the stacking process. According to this, the length of the conductive layer CL2 in the thickness direction can be shortened as compared with a case where the conductive layer CL1 does not remain, and a risk that the conductive layer CL2 may be broken can be reduced.

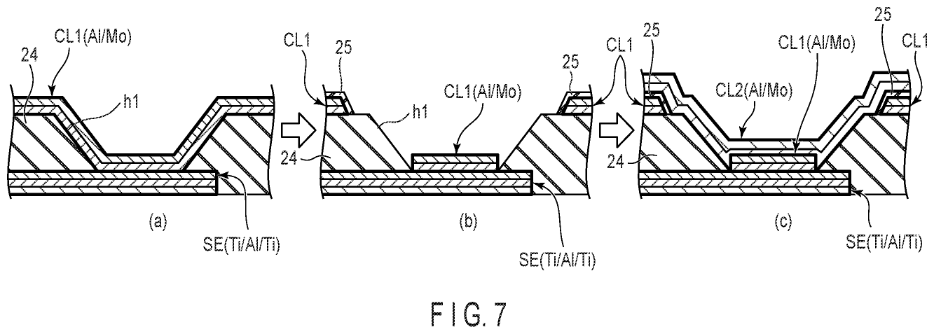

In the present embodiment, as shown in FIG. 5, the configuration in which the insulating layer 25 is provided to cover the contact hole h1 (in other words, the configuration in which the insulating layer 25 is also provided on the side surface of the contact hole h1) has been exemplified, but the configuration is not limited to this and, for example, as shown in FIG. 7, the insulating layer 25 may not be provided to cover the contact hole h1.

In this case, first, as shown in FIG. 7(a), the conductive layer CL1 is formed on the insulating layer 24 and the source electrode SE. It is assumed here that the contact hole h1 is already formed in the insulating layer 24. The conductive layer CL1 is in contact with the source electrode SE through the contact hole h1. Although illustration is omitted in FIG. 7, the resist film is formed on the conductive layer CL1 except for the part which is in contact with the side surface of the contact hole h1 after the state shown in FIG. 7(a). After that, wet etching is executed to remove the conductive layer CL1 which is in contact with the side surface of the contact hole h1. The resist film formed on the conductive layer CL1 is removed after wet etching is ended.

Next, the insulating layer 25 is formed to cover the conductive layer CL1 and the insulating layer 24 (contact hole h1). Then, the resist film is formed on the insulating layer 25 arranged at a position which does not overlap with the contact hole h1 in planar view. After that, dry etching is executed, the insulating layer 25 arranged on the side surface of the contact hole h1 and the insulating layer 25 on the conductive layer CL1 arranged in an island shape on the source electrode SE are removed, and the side surface of the contact hole h1 is exposed and the surface of the conductive layer CL1 arranged in an island shape on the source electrode SE is exposed as shown in FIG. 7(b). The resist film formed on the insulating layer 25 is removed after dry etching is ended.

After that, as shown in FIG. 7(c), the conductive layer CL2 is formed to cover the insulating layer 25 and the conductive layer CL1 (contact hole h1) which is arranged on the insulating layer 24 and the source electrode SE. The conductive layer CL2 is in contact with the conductive layer CL1 through the contact hole h1. In other words, the conductive layer CL2 is electrically connected to source electrode SE through the conductive layer CL1, similarly to the configuration shown in FIG. 5.

Even in the above-described configuration shown in FIG. 7, the various effects described above can be obtained similarly to the configuration shown in FIG. 5 since the conductive layer CL1 located under the light emitting layer LI of the light emitting element 10 is formed of a metal having a two-layer stacked structure of Al/Mo.

### Second Embodiment

Next, a second embodiment will be described. The display device 1 of the second embodiment is different from the above-described first embodiment in that the conductive layer CL1 is not formed of Al/Mo, but is composed of a lower layer formed of a metal material containing Ti as a main component, such as Ti, an alloy containing Ti, or the like and an upper layer formed of a metal material containing Al as a main component, such as Al, an alloy containing Al (i.e., Al/Ti). In addition, the present embodiment is also different from the above-described first embodiment in that the conductive layer CL2 is connected to the source electrode SE by a side contact, which will be described later in detail.

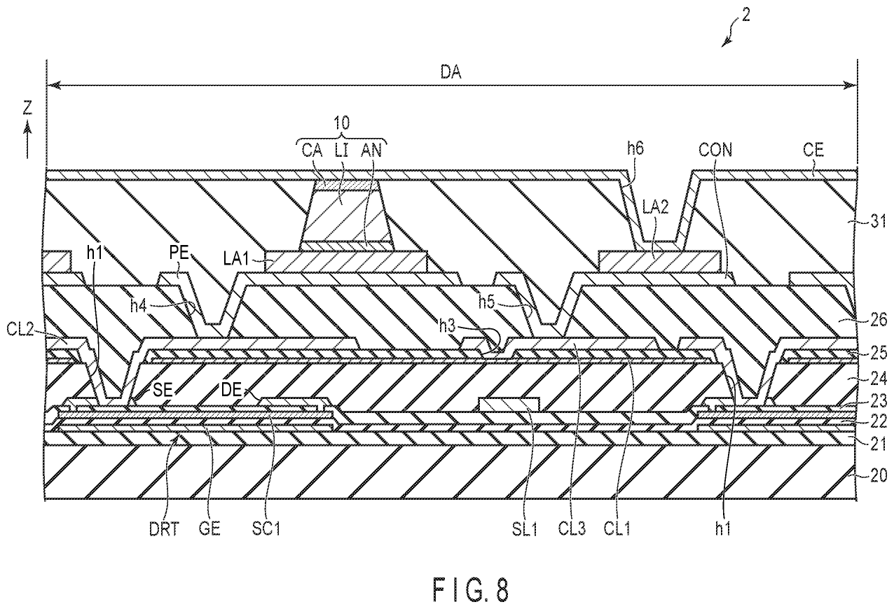

FIG. 8 is a cross-sectional view schematically showing a configuration of a display panel 2 according to the second embodiment. The description of the configuration similar to that of the display panel 2 of the first embodiment shown in FIG. 4 will be omitted, and only the configuration different from that of the display panel 2 of the first embodiment will be described.

As shown in FIG. 8, a contact hole h1 is formed in an insulating layer 24, and the contact hole h1 exposes an upper surface of an insulating layer 23. A conductive layer CL1 is provided on the insulating layer 24 except an area overlapping with the contact hole h1 in planar view. An insulating layer 25 is provided to cover the conductive layer CL1. A conductive layer CL2 is formed to cover the insulating layer 25, the insulating layer 24 and the insulating layer 23 (contact hole h1). The conductive layer CL2 is in contact with the insulating layer 23 through the contact hole h1 and is connected to a side surface of a source electrode SE.

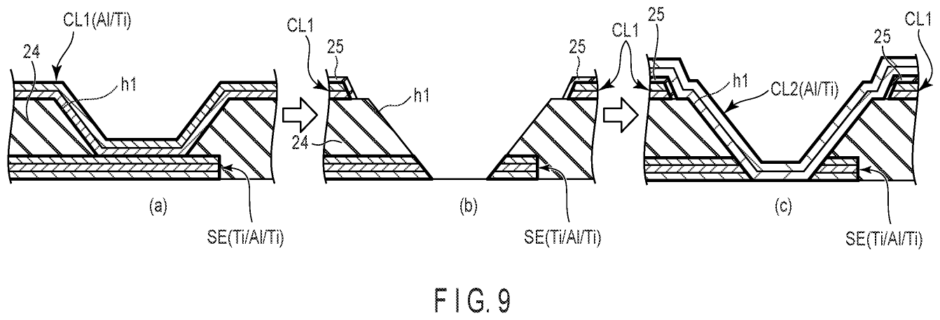

An example of a method of forming a stacked layer body from the conductive layer CL1 to the conductive layer CL2 (a stacked layer body composed of the conductive layer CL1, the insulating layer 25, and the conductive layer CL2) will be described with reference to FIG. 9. It is assumed here that the source electrode SE of the drive transistor DRT has a three-layer stacked structure of Ti/Al/Ti and that the conductive layers CL1 and CL2 have a two-layer stacked structure of Al/Ti.

First, as shown in FIG. 9(a), the conductive layer CL1 is formed on the insulating layer 24 and the source electrode SE. It is assumed here that the contact hole h1 is already formed in the insulating layer 24. The conductive layer CL1 is in contact with the source electrode SE through the contact hole h1. Although illustration is omitted in FIG. 9, a resist film is formed on the conductive layer CL1 arranged at a position which does not overlap with the contact hole h1 in planar view after the state shown in FIG. 9(a). After that, dry etching is executed to remove the conductive layer CL1 and the source electrode SE arranged at the position overlapping with the contact hole h1 in planar view. The resist film formed on the conductive layer CL1 is removed after dry etching is ended.

Next, the insulating layer 25 is formed to cover the conductive layer CL1, the insulating layer 24, and the insulating layer 23 (contact hole h1). Then, a resist film is formed on the insulating layer 25 on the conductive layer CL1. After that, dry etching is executed, the insulating layer 25 arranged at the position overlapping with the contact hole h1 in planar view is removed, and the side surface of the contact hole h1 is exposed and the surface of the insulating layer 23 is exposed as shown in FIG. 9(b). The resist film formed on the insulating layer 25 is removed after dry etching is ended.

After that, as shown in FIG. 9(c), a conductive layer CL2 is formed to cover the insulating layer 25, the insulating layer 24, and the insulating layer 23 (contact hole h1). The conductive layer CL2 is in contact with the insulating layer 23 through the contact hole h1, and is connected to the source electrode SE by side contact with the side surface of the source electrode SE.

The stacked layer body from the conductive layer CL1 to the conductive layer CL2 is formed by the method described above. As shown in FIG. 9(c), the source electrode SE is in contact with the conductive layer CL2, on the side surface. More specifically, each of Ti/Al/Ti constituting the source electrode SE surrounds Ti of the lower layer of the conductive layer CL2 and is connected to the Ti.

Even in the configuration of the above-described second embodiment, since the fact remains that the conductive layer CL1 located under the light emitting layer LI of the light emitting element 10 is formed of a metal having a two-layer stacked structure of Al/Ti, the various effects described above can be obtained similarly to the configuration indicated in the above-described first embodiment.

### Third Embodiment

Next, a third embodiment will be described. A display device 1 according to the third embodiment is different from the above-described first embodiment in that a blackened film is provided on upper surfaces of conductive layers CL1 to CL3, a pixel electrode PE, a contact electrode CON, and connection layers LA1 and LA2. In other words, the third embodiment is different from the above-described first embodiment in that the blackened film is provided on an upper surface of a metal layer located under a light emitting layer LI of a light emitting element 10 and located above a pixel circuit such as a drive transistor DRT.

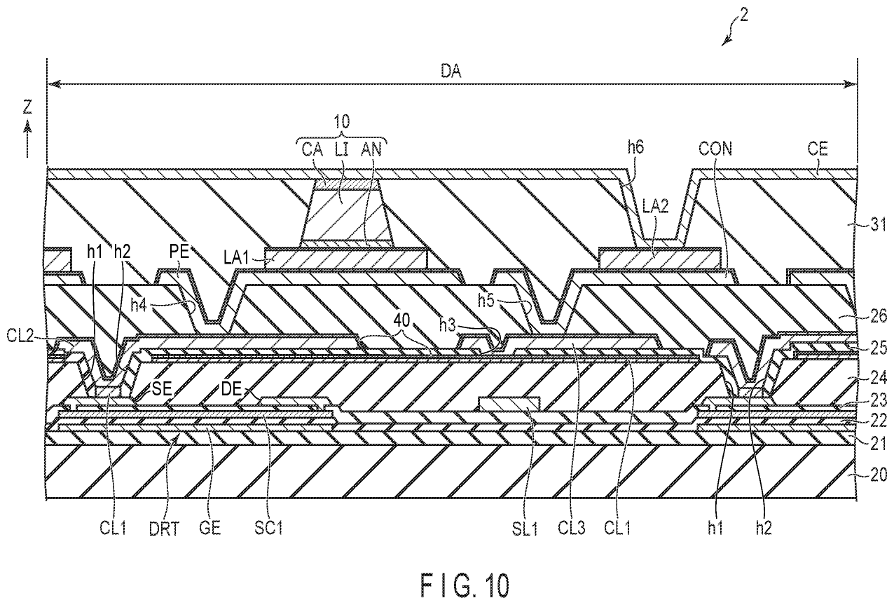

FIG. 10 is a cross-sectional view schematically showing a configuration example of a display panel 2 according to the third embodiment. The description of the configuration similar to that of the display panel 2 of the first embodiment shown in FIG. 4 will be omitted, and only the configuration different from that of the display panel 2 of the first embodiment will be described.

As shown in FIG. 10, the blackened film 40 is provided on each of upper surfaces of the conductive layers CL1 to CL3, a pixel electrode PE, a contact electrode CON, and connection layers LA1 and LA2. The blackened film 40 has, for example, a two-layer stacked structure composed of a lower layer and an upper layer. The lower layer of the blackened film 40 is formed of, for example, a metallic material or alloy material such as titanium (Ti), tantalum (Ta), or molybdenum (Mo). Incidentally, the lower layer of the blackened film 40 may be formed of a semiconductor material such as silicon (Si) or germanium (Ge). In contrast, the upper layer of the blackened film 40 is formed of a material having a refractive index of 1.7 to 2.0. More specifically, the upper layer of the blackened film 40 is formed of a material such as indium tin oxide (ITO), indium zinc oxide (IZO), zinc oxide (ZnO) or magnesium oxide (MgO). Incidentally, the upper layer of the blackened film 40 may be formed of an insulating material such as silicon nitride, aluminum nitride, or aluminum oxide.

In the configuration of the above-described third embodiment, the blackened film 40 is provided on the upper surface of each of the metal layers located under the light emitting layer LI of the light emitting device 10 and located above the pixel circuit such as the drive transistor DRT. The blackened film 40 having the above-described two-layer stacked structure comprises a function of visually blackening by using the interference effect of light. According to this, the external light reflectance can be reduced. In addition, since the lower layer of the blackened film 40 having the above-described two-layer stacked structure is formed of a metal having an excellent thermal conductivity, the heat dissipation effect can also be increased. For this reason, the problem of heat generation in the micro-LEDs can also be solved.

According to at least one of the above-described embodiments, the display device 1 (micro-LED display) capable of suppressing the degradation in display quality can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a substrate;
a pixel circuit arranged on the substrate;
an organic planarization film arranged on the substrate and covering the pixel circuit;
a second electrode electrically connected to a first electrode constituting the pixel circuit, in an area overlapping with a first contact hole formed in the organic planarization film, in planar view;
a light emitting element electrically connected to the second electrode; and
a metal layer arranged between the organic planarization film and the second electrode,
the metal layer being arranged on an entire surface of the organic planarization film, except for the area overlapping with the first contact hole in planar view.

2. The display device of claim 1, wherein
the metal layer is also arranged in an island shape on the first electrode, and
the second electrode is electrically connected to the first electrode via the metal layer arranged in the island shape.

3. The display device of claim 1, further comprising:
an insulating layer covering the organic planarization film and the metal layer, wherein
the second electrode is electrically connected to the first electrode, in an area overlapping with a second contact hole surrounded by the first contact hole, in planar view, the second contact hole being a contact hole formed in the insulating layer.

4. The display device of claim 3, wherein
a predetermined capacitor is formed between the metal layer and the second electrode opposed to each other with the insulating layer interposed therebetween.

5. The display device of claim 1, wherein
the metal layer is formed of a metal having a high reflectance.

6. The display device of claim 1, wherein
the first electrode has a three-layer stacked structure of Ti/Al/Ti,
the metal layer and the second electrode have a two-layer stacked structure of Al/Mo, and
the first electrode, the metal layer, and the second electrode overlap in the area overlapping with the first contact hole in planar view, and various metals are stacked in order of Al/Mo/Al/Mo/Ti/Al/Ti from an upper layer to a lower layer.

7. The display device of claim 1, wherein
the first contact hole is formed by cutting away a part of the first electrode in addition to the the organic planarization film, and
the second electrode is connected to a side surface of the first electrode in the area overlapping with the first contact hole in planar view.

8. The display device of claim 7, wherein
the first electrode has a three-layer stacked structure of Ti/Al/Ti,
the metal layer and the second electrode have a two-layer stacked structure of Al/Ti, and
Ti that is one of metals constituting the second electrode is connected to Ti/Al/Ti constituting the first electrode, in the area overlapping with the first contact hole in planar view.

9. The display device of claim 1, wherein
the pixel circuit includes a drive transistor for driving the light emitting element, and
the first electrode is a source electrode constituting the drive transistor.

10. The display device of claim 1, wherein
the light emitting element is a micro-LED.
